(19) United States
(12) Patent Application Publication
(10) Pub. No.: US 2020/0381540 A1
(43) Pub. Date: Dec. 3, 2020

(54) SEMICONDUCTOR DEVICE, MANUFACTURING METHOD THEREOF, AND ELECTRONIC DEVICE INCLUDING THE DEVICE

(71) Applicant: Institute of Microelectronics, Chinese Academy of Sciences, Beijing (CN)

(72) Inventors: Yongliang Li, Beijing (CN); Anyan Du, Beijing (CN); Zhenhua Wu, Beijing (CN); Chaolei Li, Beijing (CN); Wenwu Wang, Beijing (CN)

(21) Appl. No.: 16/845,351

(22) Filed: Apr. 10, 2020

(30) Foreign Application Priority Data
Jun. 3, 2019 (CN) 201910477236.7

(51) Int. Cl. H01L 29/66; H01L 29/06; H01L 29/78; H01L 21/8234

(52) U.S. Cl. CPC H01L 29/66818; H01L 21/823431; H01L 29/785; H01L 29/0669

(57) ABSTRACT

The disclosure provides a semiconductor device, a manufacturing method thereof, and an electronic device including the device. The semiconductor device includes: a substrate, the substrate being a silicon substrate or an SOI substrate; a SiGe Fin formed on the substrate, wherein the SiGe Fin is a sandwich-like SiₓGe₁₋ₓ/Si_{y}Ge_{1-y}/Si_{z}Ge_{1-z} structure with different Ge contents in the horizontal direction, where x is 0.05˜0.95, y is 0.1˜0.9, and z is 0.05˜0.95; and a shallow trench isolation region disposed on the substrate and adjacent to all sides of the SiGe Fin, wherein a top surface of the SiGe Fin facing away from the substrate protrudes from the shallow trench isolation region. The disclosure proposes a device structure of a sandwich-like SiₓGe₁₋ₓ/Si_{y}Ge_{1-y}/Si_{z}Ge_{1-z} Fin structure with different Ge contents, which can adjust the Ge content to change the band gap, thereby adjusting the threshold, and improving electrical properties such as mobility (effective mass change) and leakage. The disclosure can be applied to devices such as FinFETs or vertical nanowires.

### CLAIM FOR PRIORITY

This application claims the benefit of priority of Chinese Application Serial No. 201910477236.7, which is hereby incorporated by reference in its entirety.

### TECHNICAL FIELD

The present disclosure relates to the field of semiconductors, and in particular, to a semiconductor device, a manufacturing method thereof, and an electronic device including the device.

### BACKGROUND

With the shrinking of the feature size of the device, the three-dimensional FinFETs and nanowire devices with SiGe high mobility channels have become hotspots of research. Among them, threshold control of 3D devices such as SiGe FinFET is an important challenge. This is because the Fin of conventional FinFET is about 50 nm high and the width of the Fin is about 15 nm. The doping concentration adjusted by Vt is generally in the order of 5E17 to 3E18 cm⁻³, and the number of implanted impurities is about 20. The fluctuation of the process causes difficulties in Vt control. At the same time, because it is difficult to achieve uniformity of plasma or in-situ epitaxial doping in such a small Fin, impurity implantation also brings the problem about the influence of scattering on mobility.

Therefore, a new Fin device structure is urgently needed, which can adjust the threshold, improve the electrical properties such as mobility (effective mass change) and leakage.

### SUMMARY OF THE DISCLOSURE

An object of the present disclosure is to provide, at least in part, a semiconductor device, a manufacturing method thereof, and an electronic device including the semiconductor device to solve the problem about difficult threshold control.

According to an aspect of the present disclosure, there is provided a semiconductor device, including: a substrate, wherein the substrate comprises a silicon substrate or an SOI substrate; a SiGe Fin formed on the substrate, wherein the SiGe Fin is a sandwich-like SiₓGe₁₋ₓ/Si_{y}Ge_{1-y}/Si_{z}Ge_{1-z} structure with different Ge contents in the horizontal direction, where the value of x is 0.05˜0.95, the value of y is 0.1˜0.9, and the value of z is 0.05˜0.95; and a shallow trench isolation region (i.e., STI), disposed on the substrate and adjacent to the all sides of the SiGe Fin, wherein a top surface of the SiGe Fin facing away from the substrate protrudes from the shallow trench isolation region.

This device has a device structure of a sandwich-like SiₓGe₁₋ₓ/Si_{y}Ge_{1-y}/Si_{z}Ge_{1-z} Fin structure with different Ge contents, which can adjust the Ge content to change the band gap, thereby adjusting the threshold, and improving electrical properties such as mobility (effective mass change) and leakage. The device structure may be applied to devices such as FinFETs or vertical nanowires.

Preferably, the oxide layer is disposed between the shallow trench isolation region and a sidewall of the SiGe Fin.

Preferably, a bottom surface of the SiGe Fin facing the substrate and an bottom surface of the shallow trench isolation region facing the substrate are coplanar; or a bottom surface of the SiGe Fin facing the substrate is higher than a bottom surface of the shallow trench isolation region facing the substrate; or a bottom surface of the SiGe Fin facing the substrate is lower than a bottom surface of the shallow trench isolation region facing the substrate.

Preferably, a cross section of a bottom surface of the SiGe Fin facing the substrate comprises a horizontal plane, an arcuate plane, or a triangular plane.

Preferably, a width of the middle Si_{y}Ge_{1-y} layer of the SiGe Fin is 1/5 to 1/2 of the width of the entire SiGe Fin.

Preferably, a stress layer is provided between the shallow trench isolation region and the oxide layer.

Preferably, a concentration of Si in the middle Si_{y}Ge_{1-y} layer of the SiGe Fin is 3% to 30% higher than that in the SiₓGe₁₋ₓ or Si_{z}Ge_{1-z} layer on both sides.

Preferably, a SiGe layer or a pure Ge layer is further provided between a bottom surface of the SiGe Fin facing the substrate and the substrate, wherein Ge content in the SiGe layer or the pure Ge layer is higher than the Ge content in the SiGe Fin.

Preferably, the concentration of Ge in the middle Si_{y}Ge_{1-y} layer of the SiGe Fin is 3% to 30% higher than that in the SiₓGe₁₋ₓ or Si_{z}Ge_{1-z} layer on both sides.

According to another aspect of the present disclosure, a method for manufacturing a semiconductor device is provided. The method includes: forming a shallow trench isolation region in a substrate, wherein a portion of the substrate between the shallow trench isolation regions comprises a bulk silicon Fin structure; selectively removing the bulk silicon Fin structure to recess the body silicon Fin structure to form a trench, and growing a semiconductor material at the trench to form a SiGe Fin, wherein the SiGe Fin comprises a sandwich-like SiₓGe₁₋ₓ/Si_{y}Ge_{1-y}/Si_{z}Ge_{1-z} structure with different Ge contents in the horizontal direction; recessing the shallow trench isolation region, wherein the a top surface of the SiGe Fin facing away from the substrate protrudes from the shallow trench isolation region on both sides.

This method is different from the scheme in which a SiGe channel is directly formed on Si Fin, or the scheme in which the structure of a thin layer of Si is epitaxially formed on a high mobility channel and the surface of the high mobility channel is passivated. Although both of these schemes form a sandwich-like structure of Si/high mobility channel/Si or high mobility channel/Si/high mobility channel to improve device characteristics, the Ge content of the high mobility channel itself is constant. The disclosure proposes a sandwich-like SiₓGe₁₋ₓ/Si_{y}Ge_{1-y}/Si_{z}Ge_{1-z} structure scheme in which the content of Ge is controlled in a SiGe high mobility channel to form different Ge contents, further improving device characteristics.

Preferably, the step of forming a shallow trench isolation region further includes: forming a bulk silicon Fin structure and a trench on the substrate by a sidewall pattern transfer technique or other photolithography techniques; filling a dielectric material so that the dielectric material covers the trench and a top surface of the bulk silicon Fin structure; etching back the dielectric material to expose the top surface of the bulk silicon Fin structure.

Preferably, an oxide layer is formed on the sidewall and the top surface of the bulk silicon Fin structure.

Preferably, before forming the SiGe Fin, the method further includes: mechanically planarizing the semiconductor material to remove the semiconductor material located above the top surface of the shallow trench isolation region.

Preferably, when the bulk silicon Fin structure is selectively removed, the bulk silicon Fin structure may be partially or completely removed or even the substrate is recessed, and the cross-section of a surface facing the substrate after the removal may be a horizontal plane, an arcuate plane, or a triangular plane.

Preferably, the width of the middle Si_{y}Ge_{1-y} layer of the sandwich-like structure of the SiGe Fin is 1/5 to 1/2 of the width of the entire SiGe Fin.

Preferably, a stress layer is formed between the shallow trench isolation region and the oxide layer.

Preferably, a concentration of Si in the Si_{y}Ge_{1-y}e layer in the middle of the semiconductor material of the SiGe Fin with the sandwich-like structure is 3% to 30% higher than that in the SiₓGe₁₋ₓ or Si_{z}Ge_{1-z} layer on both sides.

Preferably, after selectively removing the bulk silicon Fin structure and before growing the semiconductor material, a layer of SiGe layer or a pure Ge layer is selectively formed in the trench by a process such as reduced pressure chemical vapor deposition process, wherein Ge content in the SiGe layer or the pure Ge layer is higher than that in SiGe Fins.

Preferably, a concentration of Ge in the middle SiGe layer of the sandwich-like structure of the SiGe Fin is 3% to 30% higher than that in the SiₓGe₁₋ₓ or Si_{z}Ge_{1-z} layer on both sides.

According to still another aspect of the present disclosure, there is provided an electronic device including an integrated circuit formed of the semiconductor device described above.

### BRIEF DESCRIPTION OF THE DRAWINGS

When read in conjunction with the accompanying drawings, various aspects of the disclosure may be best understood from the following detailed description. It should be noted that according to standard practice in the industry, various components are not drawn to scale. In fact, for the sake of clarity, the dimensions of the various components can be arbitrarily increased or decreased.

FIGS. 1a to 1f are flowcharts of forming a SiGe Fin structure according to an embodiment of the present disclosure.

FIGS. 2a to 2e are shape diagrams formed after a bulk silicon Fin structure is removed according to an embodiment of the present disclosure.

FIGS. 3a to 3b are schematic diagrams of a SiGe Fin with a middle Si-rich layer formed according to an embodiment of the present disclosure.

FIG. 4 is an electron micrograph of a semiconductor device having a high mobility channel according to an embodiment of the present disclosure.

FIGS. 5a to 5e are flowcharts of forming a SiGe Fin structure according to another embodiment of the present disclosure.

FIGS. 6a to 6b are schematic diagrams of a SiGe Fin with a middle Ge-rich layer formed according to an embodiment of the present disclosure.

### DETAILED DESCRIPTION

The following disclosure provides many different embodiments or examples to achieve different features of the disclosure. Specific examples of components and arrangements will be described below to simplify the present disclosure. Of course, these are merely examples and are not intended to limit the disclosure. For example, in the following description, forming a first component above or on a second component may include an embodiment where the first component and the second component are in direct contact, or may include an embodiment in which an additional component is formed between the first component and the second component to cause the first component and the second component not in direct contact.

In addition, for the convenience of description, spatial relation terms such as “below”, “under”, “lower”, “above/on”, “upper” and the like may be used in this article to describe the relationship of one element or component to another element or component. In addition to the orientations shown in the figures, spatially relative terms are intended to include different orientations of the device in use or operation. The device may be otherwise positioned (rotated 90 degrees or at other orientations), and the spatial relationship descriptors used herein may be interpreted accordingly as well.

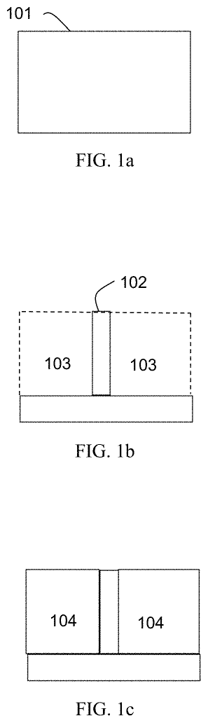

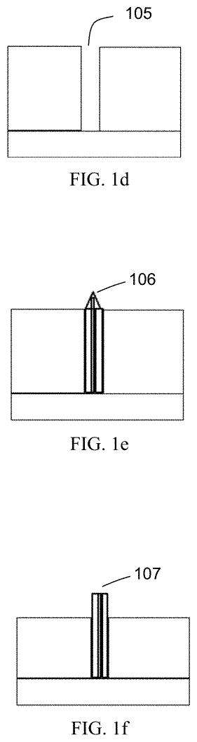

FIGS. 1a to 1f are flowcharts of forming a SiGe Fin structure according to an embodiment of the present disclosure, showing one embodiment of a process for forming a Fin structure of a sandwich-like SiₓGe₁₋ₓ/Si_{y}Ge_{1-y}/Si_{z}Ge_{1-z} structure with different Ge contents.

As shown in FIG. 1a, a substrate 101 is provided. The substrate 101 may be a single crystal silicon substrate. Optionally, it includes, but is not limited to, a semiconductor on insulator (SOI) substrate, a compound semiconductor substrate (such as a SiC substrate), an alloy semiconductor substrate (such as a SiGe substrate), and the like. In some embodiments, the substrate may include a doped epitaxial layer.

A SiGe Fin is formed on the substrate, where the SiGe Fin is a sandwich-like SiₓGe₁₋ₓ/Si_{y}Ge_{1-y}/Si_{z}Ge_{1-z} structure with different Ge contents in the horizontal direction, where the value of x is 0.05˜0.95 and the value of y is 0.1 to 0.9, and the value of z is 0.05 to 0.95. Specifically, as shown in FIG. 1b, on the substrate 101, a trench 103 and a bulk silicon Fin structure 102 are formed on the substrate 101 through a sidewall transfer process. And then by using a HARP process, SiO2 material is used to deposit a shallow trench isolation region at the trench. The HARP process is preferably performed in two steps. The specific process conditions are as follows: the first step is at a pressure of 600 Torr, TEOS 1200 mg/min, and He carrier gas 6000 sccm, N₂ carrier gas 12000 sccm, O₃ 12000 sccm, N₂ 3000 sccm, and a temperature of 540° C.; the second step is at a pressure of 600 Torr, TEOS 2700 mg/min, He carrier gas 3000 sccm, N₂ carrier gas 18000 sccm, O₃ 8000 sccm, O₂ 16000 sccm, N₂ 3000 sccm, a temperature of 540° C. The deposition thickness in the first step is 1500 Å and the time is 130 s; the deposition thickness in the second step is generally 500-2500 Å, and the deposition thickness in the second step depends on the total thickness required for deposition. Of course, the HARP process can also select a multi-step deposition method as required. The specific process conditions of the multi-step deposition can refer to the above-mentioned process conditions. The deposition thickness in each step is determined according to the total deposition thickness. As shown in FIG. 1c, the present disclosure can form the shallow trench isolation region with larger stress by using the HARP process. As shown in FIG. 1d, the bulk silicon Fin structure 102 is selectively removed to recess the bulk silicon Fin structure 102 located between two parts of the shallow trench isolation region 104, forming a trench 105. As shown in FIG. 1e, the semiconductor material 106 is selectively epitaxial grown at the trench 105 using a precursor, such as silane and germane, and HCl gas in an H₂ atmosphere under a reduced pressure chemical vapor deposition at 650° C. The selected semiconductor material 106 is a SiGe material; the formed SiGe Fin is a sandwich-like SiₓGe₁₋ₓ/Si_{y}Ge_{1-y}/Si_{z}Ge_{1-z} structure with different Ge contents in the horizontal direction, where x is 0.05˜0.95, y is 0.1˜0.9, z is 0.05˜0.95. The Si content in the middle layer Si_{y}Ge_{1-y} of the sandwich-like structure is higher than the Si content in the SiₓGe₁₋ₓ and Si_{z}Ge_{1-z} layers on both sides when the substrate is a single crystal silicon substrate or an SOI substrate. The Ge content in the middle layer Si_{y}Ge_{1-y} of the sandwich-like structure is higher than the Ge content in the SiₓGe₁₋ₓ and Si_{z}Ge_{1-z} layers on both sides when the substrate is a SiGe substrate or a pure Ge substrate. Since the shallow trench isolation regions on both sides of the SiGe Fin have a large stress, the stress effect of the shallow trench isolation regions makes it possible for Si or Ge in the substrate to enter into the SiGe Fin during selective epitaxy of the semiconductor material, so as to easily form a Si-rich or Ge-rich SiGe layer in the middle (compared to SiGe materials on both sides). The sandwich-like structure will affect the energy band and carrier distribution of the entire SiGe Fin, which is beneficial for adjusting electrical parameters such as the mobility of SiGe carriers, threshold, and leakage.

A shallow trench isolation region (STI) is disposed on the substrate and adjacent to all sides of the SiGe Fin. a top surface of the SiGe Fin facing away from the substrate protrudes from the shallow trench isolation regions on both sides. According to an embodiment of the present disclosure, the planarization process is performed first, and then the semiconductor material 106 of the sandwich-like structure is exposed through wet etching of hydrofluoric acid, protruding from the shallow trench isolation regions on both sides to form a SiGe Fin structure 107, and the subsequent process is the same as that for FinFET devices.

The semiconductor device of the present disclosure has a device structure of a sandwich-like SiₓGe₁₋ₓ/Si_{y}Ge_{1-y}/Si_{z}Ge_{1-z} Fin structure with different Ge contents, which can adjust the Ge content to change the band gap, thereby adjusting the threshold, and improving electrical properties such as mobility (effective mass change) and leakage. The semiconductor device Fin structure is different from a structure in which a SiGe channel is formed directly on Si Fin, or a structure in which a thin layer of Si is epitaxially grown on a high mobility channel to passivate the surface of the high mobility channel. Although both of these structures is to form a sandwich-like structure of Si/high mobility channel/Si or high mobility channel/Si/high mobility channel to improve device characteristics, the Ge content of the high mobility channel itself is constant. The disclosure proposes a sandwich-like SiₓGe₁₋ₓ/Si_{y}Ge_{1-y}/Si_{z}Ge_{1-z} structure scheme in which the content of Ge is controlled in a SiGe high mobility channel to form different Ge contents, further improving device characteristics. The disclosure can be applied to devices such as FinFETs or vertical nanowires.

Further, in combination with the above embodiments, the present disclosure also provides other optional embodiments, specifically as follows. An oxide layer is further provided between the shallow trench isolation region and a sidewall of the SiGe Fin. The oxide layer can be realized by thermal oxidation or rapid annealing, and the thickness is 0.5-5 nanometers. For example, when rapid annealing is selected, the preferred processing conditions are rapid annealing at 950° C. under a pressure of 10 Torr and a ratio of O₂ to H₂ of 200:1. The annealing process forms an oxide layer, and the time for the rapid annealing process is related to the thickness of the oxide layer.

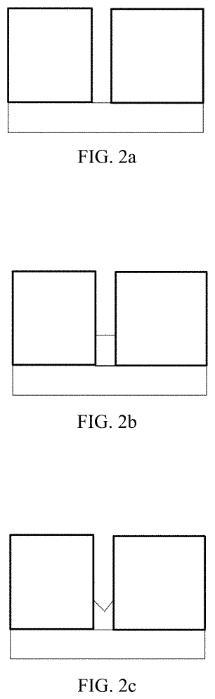

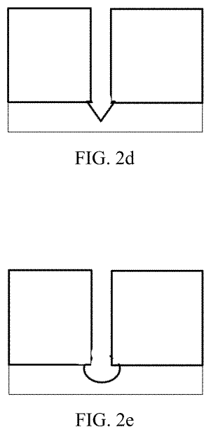

Further, in combination with the above embodiments, the present disclosure also provides other optional embodiments. Specifically, the bottom face of the SiGe Fin facing the substrate may be coplanar with the bottom face of the shallow trench isolation region facing the substrate. Alternatively, the bottom surface of the SiGe Fin facing the substrate may also be higher or lower than the bottom surface of the shallow trench isolation region facing substrate. Furthermore, the cross section of the bottom surface of the SiGe Fin facing the substrate can also form different structures such as a horizontal plane, an arcuate plane, or a triangular plane. In this embodiment, when the bulk silicon Fin structure 102 is selectively removed, the bulk silicon Fin structure 102 can be partially or completely removed or the substrate 101 can be recessed. As shown in FIGS. 2a to 2e, the cross-sectional shape of a surface facing the substrate after the bulk silicon Fin structure is removed can be a horizontal plane, an arcuate plane, or a triangular plane. The difference in the shapes is related to the selected etching back process. For example, the surface after removal of the bulk silicon Fin structure 102 is easily formed into a triangular shape by using a TMAH wet etching process, and a horizontal surface is easily obtained by removing the bulk silicon Fin structure 102 through a dry etching process using a gas such as HCl, thereby obtaining a different SiGe Fin structure in the embodiment. It should be noted that the deeper the substrate 101 is recessed when the bulk silicon Fin structure is removed, the higher the Si content (when the substrate is a single crystal silicon substrate or an SOI substrate) or the Ge content (when the substrate is a SiGe substrate or a pure Ge substrate) is contained in the middle layer of the sandwich-like SiGe Fin structure formed when the semiconductor material is grown under a reduced pressure chemical vapor deposition. Therefore, the present disclosure can also control the level of Si content in the middle layer of the sandwich-like structure by controlling the recess depth in the substrate when the bulk silicon Fin structure is removed.

Further, in combination with the above embodiments, the present disclosure also provides other optional embodiments. In this embodiment, the width of the middle Si_{y}Ge_{1-y} layer of the sandwich-like SiGe Fin structure is preferably 1/5 to 1/2 of the width of the entire SiGe Fin. The width of the Si_{y}Ge_{1-y} layer is related to the depth and shape of the etching back process.

Further, in combination with the above embodiments, the present disclosure also provides other optional embodiments wherein a stress layer is further provided between the shallow trench isolation region and the oxide layer. The stress layer can be realized by atomic layer deposition (ALD), plasma enhanced chemical vapor deposition (PECVD), physical vapor deposition (PVD), chemical vapor deposition (CVD), and other methods. The stress layer may be silicon oxide, silicon nitride, or a phase change material, but is not limited to the above three types of materials. By providing a stress layer and providing a greater stress effect through the stress layer, when the SiGe Fin is selectively epitaxially formed, the Si-rich or Ge-rich ability in the middle layer of the sandwich-like SiGe Fin structure formed can be further enhanced (compared with SiGe materials on both sides). Specifically, when the substrate in contact with the formed SiGe Fin is a single crystal silicon substrate or an SOI substrate, the Si-rich ability in the middle layer of the formed sandwich-like SiGe Fin structure is stronger; and when the substrate in contact with the formed SiGe Fin is a SiGe substrate (wherein the Ge content in the SiGe substrate is higher than the Ge content in the SiGe Fin) or a pure Ge substrate, the Ge-rich ability in the middle layer of the formed sandwich-like SiGe Fin structure is stronger.

Further, in combination with the above embodiments, the present disclosure also provides some other optional embodiments. In this embodiment, preferably, a concentration of Si in the middle Si_{y}Ge_{1-y} layer of the sandwich-like SiGe Fin structure is 3% to 30% higher than that in the SiₓGe₁₋ₓ or Si_{z}Ge_{1-z} layer on both sides, preferably 5%-10% higher. The difference between a concentration of Si in the Si_{y}Ge_{1-y} layer and that in the SiₓGe₁₋ₓ or Si_{z}Ge_{1-z} layer on both sides is mainly related to the width of the Si_{y}Ge_{1-y} layer, the stress of the STI and the process in which the stress layer is provided.

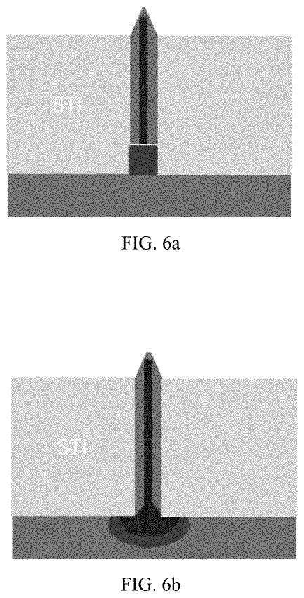

Further, in combination with the above embodiments, the present disclosure also provides other optional embodiments. For example, after selectively removing the bulk silicon Fin structure and before growing the semiconductor material, a SiGe layer or a pure Ge layer is selectively formed on the substrate in the bulk silicon Fin trench through a process such as a reduced pressure chemical vapor deposition, as shown in FIG. 6. The Ge content in the SiGe layer or the pure Ge layer is higher than the Ge content in the SiGe Fin. A concentration of Ge in the middle Si_{y}Ge_{1-y} layer of the sandwich-like SiGe Fin structure thus formed is 3% to 30% higher than that in the SiₓGe₁₋ₓ or Si_{z}Ge_{1-z} layer on both sides. The difference between a concentration of Ge in the Si_{y}Ge_{1-y} layer and that in the SiₓGe₁₋ₓ or Si_{z}Ge_{1-z} layer on both sides is mainly related to the width of the Si_{y}Ge_{1-y} layer, the stress of the STI and the process in which the stress layer is provided.

The disclosure also provides a method for manufacturing a semiconductor device, which specifically includes the following process steps:

S1. Forming a shallow trench isolation region in a substrate, wherein a portion of the substrate between the shallow trench isolation regions is a bulk silicon Fin structure.

In this step, as shown in FIG. 1b, a trench 103 and a bulk silicon Fin structure 102 are formed on the substrate 101 through a sidewall transfer process. Also, the pattern definition of the bulk silicon Fin structure may be provided by using photolithography, and the preparation of the bulk silicon Fin structure 102 may be realized by using the dry etching process. As shown in FIG. 1c, a dielectric material is filled in the trench 103. In the present disclosure, a dielectric material is deposited by using a HARP process, wherein the dielectric material includes silicon oxide. The HARP process conditions are preferably as follows: the first step is at a pressure of 600 Torr, TEOS 1200 mg/min, He carrier gas 6000 sccm, N₂ carrier gas 12000 sccm, O₃ 12000 sccm, N₂ 3000 sccm, a temperature of 540° C.; the second step is at a pressure of 600 Torr, TEOS 2700 mg/min, He carrier gas 3000 sccm, N₂ carrier gas 18000 sccm, O₃ 8000 sccm, O_{2 16000} sccm, N₂ 3000 sccm, a temperature of 540° C. The deposition thickness in the first step is 1500 Å and the time is 130 s; the deposition thickness in the second step is generally 500-2500 Å. The deposition thickness in the second step is determined by the total thickness required for deposition. Of course, the HARP process can also select a multi-step deposition method as required. The specific process conditions of the multi-step deposition can refer to the above-mentioned process conditions. The deposition thickness in each step is determined according to the total deposition thickness. The deposited dielectric material covers the entire trench 103 and the upper portion of the bulk silicon Fin structure. Subsequently, planarization is performed to remove excess dielectric material, exposing the top of the bulk silicon Fin structure. The remaining portion of the dielectric material forms the STI region 104. In some embodiments, the STI region comprises silicon oxide.

S2. Selectively removing the bulk silicon Fin structure, recessing the bulk silicon Fin structure to form a trench, and growing a semiconductor material at the trench to form a SiGe Fin, wherein the SiGe Fin is a sandwich-like SiₓGe₁₋ₓ/Si_{y}Ge_{1-y}/Si_{z}Ge_{1-z} structure with different Ge contents in the horizontal direction.

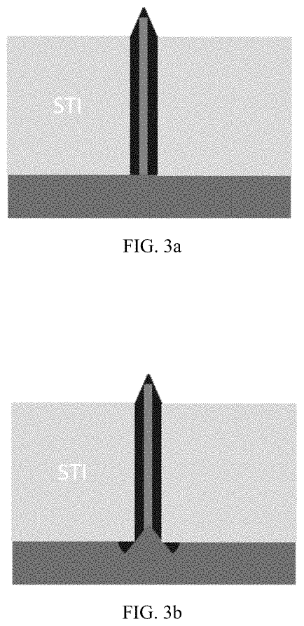

In this step, as shown in FIG. 1d, the bulk silicon Fin structure 102 is selectively removed. The bulk silicon Fin structure 102 may be removed by wet etching process (such as TMAH) or dry etching process (such as HCl gas or HBr/Cl₂ mixed gas, etc.) or a combination of wet etching and dry etching. The bulk silicon Fin structure 102 between the two portions of the shallow trench isolation region 104 is recessed to form a trench 105. As shown in FIG. 1e, the semiconductor material 106 is selectively epitaxial grown from a trench 105 using a precursor, such as silane and germane, and HCl gas in an H₂ atmosphere under a reduced pressure chemical vapor deposition at 650° C. The semiconductor material 106 is a sandwich-like SiₓGe₁₋ₓ/Si_{y}Ge_{1-y}/Si_{z}Ge_{1-z} structure with different Ge contents in the horizontal direction. In one embodiment, the semiconductor material 106 of such a sandwich-like structure is realized by selective epitaxy. This is because the stress effect of the STI region causes a Si-rich SiGe layer to be easily formed in the middle during the selective epitaxy of the SiGe material (compared to SiGe material on both sides). The deeper the substrate 101 is recessed when the bulk silicon Fin structure 102 is removed, the more obvious the Si-rich SiGe is formed, as shown in FIGS. 3a to 3b.

S3. Recessing the shallow trench isolation region, so that a top surface of the SiGe Fin facing away from the substrate protrudes from the shallow trench isolation regions on both sides.

In this step, as shown in FIG. 1f, the shallow trench isolation region is recessed, and a portion of the semiconductor material 106 located above the top surface of the remaining portion of the shallow trench isolation region 104 forms a SiGe Fin structure 107. According to an embodiment of the present disclosure, the STI region is first planarized, and then subjected to wet etching of hydrofluoric acid to expose the semiconductor material 106 of the sandwich-like structure to form the SiGe Fin structure 107. The subsequent process and the preparation process of FinFET devices are the same.

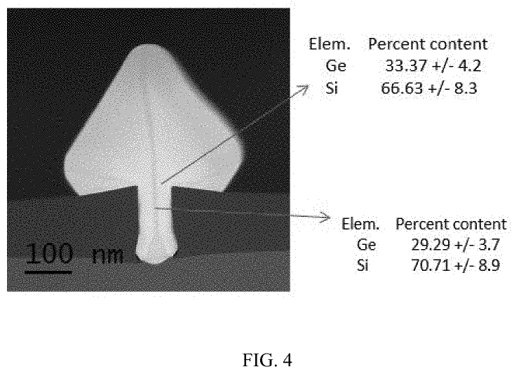

The SiGe Fin structure formed by FIGS. 1a to 1f (as shown in FIG. 4) is different from the scheme in which a SiGe channel is formed directly on Si Fin, or the scheme in which the structure of a thin layer of Si is epitaxially formed on a high mobility channel to passivate the surface of the high mobility channel. Although both of these schemes form a sandwich-like structure of Si/high mobility channel/Si or high mobility channel/Si/high mobility channel to improve device characteristics, the Ge content of the high mobility channel itself is constant. The disclosure proposes a sandwich-like SiₓGe₁₋ₓ/Si_{y}Ge_{1-y}/Si_{z}Ge_{1-z} structure scheme in which the content of Ge is controlled in a SiGe high mobility channel to form different Ge contents, further improving device characteristics.

Further, in combination with the above embodiments, the present disclosure also provides other optional embodiments. In this embodiment, before the trench is filled with a dielectric material, an oxide layer is formed on the sidewall and the top surface of the bulk silicon Fin structure 102. The oxide layer is mainly for removing the damage when etching the silicon Fin and the rounding of the top, which can be achieved by thermal oxidation or rapid annealing treatment, and the thickness is 0.5-5 nm. In this embodiment, a rapid annealing process is preferably used to form the oxide layer. The specific processing conditions of the rapid annealing process are at a temperature of 950° C., a pressure of 10 Torr, and the ratio of O₂ and H₂ 200:1, to form the oxide layer.

Further, in combination with the above embodiments, the present disclosure also provides other optional embodiments. In this embodiment, before forming the SiGe Fin structure, the semiconductor material 106 is planarized by a CMP process to remove the portion of the semiconductor material 106 with the sandwich-like structure beyond the top surface of the STI region.

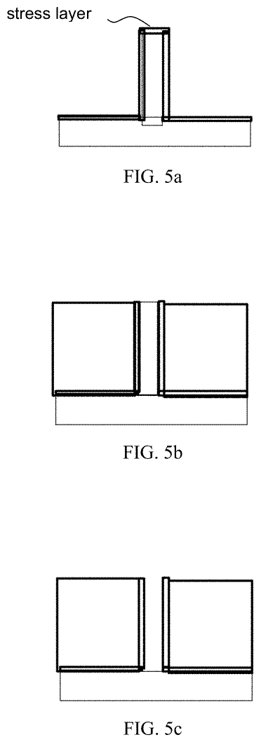

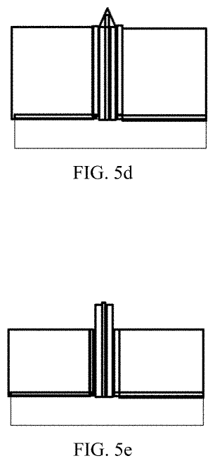

Further, in combination with the above embodiments, the present disclosure also provides some optional embodiments. In this embodiment, FIGS. 5a to 5f are flowcharts of forming a SiGe Fin structure according to another embodiment of the present disclosure. Among them, part of the processes are the same as the processes shown in FIGS. 1a to FIG. 1e, and is not repeated here. The difference is that after the bulk silicon Fin structure is formed or the bulk silicon Fin structure and the oxide layer structure are formed, a thin layer of stress providing layer is formed on the sidewall and the top surface of the bulk silicon Fin structure or the bulk silicon Fin structure and the oxide layer structure. The stress layer can provide greater stress to the silicon substrate at the trench, which facilitates forming a sandwich-like structure with rich-Si or rich-Ge in the middle during epitaxy. The stress layer can be realized by atomic layer deposition (ALD), plasma enhanced chemical vapor deposition (PECVD), physical vapor deposition (PVD), chemical vapor deposition (CVD), and other methods. The stress layer may be silicon oxide, silicon nitride, or a phase change material, but is not limited to the above three types of materials. Then the STI oxide layer is deposited and a CMP is performed, the bulk silicon Fin structure is exposed and then removed. After that, when selective epitaxy of SiGe are performed, it is easier to form a sandwich-like SiₓGe₁₋ₓ/Si_{y}Ge_{1-y}/Si_{z}Ge_{1-z} structure with different Ge contents than using a structure in which only the STI oxide layer is used to provide stress. And thus, it is beneficial to adjust Vt, energy band structure, mobility, etc.

Further, in combination with the above embodiments, the present disclosure also provides other optional embodiments. In this embodiment, when the bulk silicon Fin structure 102 is selectively removed, the bulk silicon Fin structure 102 can be partially or completely removed or even the substrate 101 is recessed. As shown in FIGS. 2a to 2e, the surface shape after removal of the bulk silicon Fin structure may be horizontal, round, or triangular. The difference in the shapes is related to the selected etching back process. For example, the surface after the removal of the bulk silicon Fin structure 102 is easily formed into a triangular shape by using a TMAH wet etching process, and a horizontal surface is easily obtained by removing the bulk silicon Fin structure 102 through a dry etching process using a gas such as HCl.

Further, in combination with the above embodiments, the present disclosure also provides some optional embodiments. In this embodiment, in the semiconductor material 106 of the sandwich-like structure, the width of the middle Si_{y}Ge_{1-y} layer is 1/5 to 1/2 of the width of the entire semiconductor material 106 (that is, the SiGe Fin), and a concentration of Si in the middle Si_{y}Ge_{1-y} layer is 3% to 30% higher than that in the SiₓGe₁₋ₓ or Si_{z}Ge_{1-z} layer on both sides. The sandwich-like Fin structure will affect the energy band and carrier distribution of the entire SiGe Fin, which is beneficial for adjusting electrical parameters such as the mobility of SiGe carriers, threshold, and leakage .

In other embodiments, in order to meet the concession requirements of the device, a sandwich-like SiGe structure with a Ge-rich middle layer can also be realized. The specific method is: after selective removal of the bulk silicon Fin structure and before selective epitaxy of SiGe, first, a layer of SiGe with a higher Ge content than the SiGe Fin or even a pure Ge layer is selectively formed by a process such as a reduced pressure chemical vapor deposition, and then the epitaxy of the SiGe sandwich-like Fin structure is performed. Other processes are the same as that of forming the SiGe sandwich-like structure with the middle Si-rich layer. A concentration of Ge in the middle Si_{y}Ge_{1-y} layer of the SiGe sandwich-like Fin structure thus formed is 3% to 30% higher than that in the SiₓGe₁₋ₓ or Si_{z}Ge_{1-z} layer on both sides. FIGS. 6a to 6b are schematic diagrams of SiGe Fins with a middle Ge-rich layer.

The disclosure proposes a device structure of a sandwich-like SiₓGe₁₋ₓ/Si_{y}Ge_{1-y}/Si_{z}Ge_{1-z} Fin structure with different Ge contents, which can adjust the Ge content to change the band gap, thereby adjusting the threshold, and improving electrical properties such as mobility (effective mass change) and leakage. The sandwich-like Fin structure defined in the present disclosure can be applied to devices such as FinFETs or vertical nanowires.

The foregoing has discussed the components of several embodiments so that those skilled in the art may better understand the aspects of the present disclosure. Those skilled in the art should understand that the present disclosure can be easily used as a basis to design or modify other processes and structures for achieving the same purpose and/or achieving the same advantages as the embodiments described in the present disclosure. Those skilled in the art should also realize that this equivalent configuration does not depart from the spirit and scope of the present disclosure, and that they can make various changes, substitutions, and alterations without departing from the spirit and scope of the present disclosure.

I/We claim:

1. A semiconductor device, comprising:
a substrate;
a SiGe Fin formed on the substrate, wherein the SiGe Fin is a sandwich-like SiₓGe₁₋ₓ/Si_{y}Ge_{1-y}/Si_{z}Ge_{1-z} structure with different Ge contents in a horizontal direction, where a value of x is 0.05˜0.95, a value of y is 0.1˜0.9, a value of z is 0.05˜0.95; a content of Si in a middle Si_{y}Ge_{1-y} layer of the sandwich-like structure is higher than that in the SiₓGe₁₋ₓand Si_{z}Ge_{1-z} layers on both sides, or a content of Ge in the middle Si_{y}Ge_{1-y} layer of the sandwich-like structure is higher than that in the SiₓGe₁₋ₓ and Si_{z}Ge_{1-z} layers on both sides; and
a shallow trench isolation region disposed on the substrate and adjacent to all sides of the SiGe Fin, wherein a top surface of the SiGe Fin facing away from the substrate protrudes from the shallow trench isolation region.

2. The semiconductor device according to claim 1, wherein an oxide layer is disposed between the shallow trench isolation region and a sidewall of the SiGe Fin.

3. The semiconductor device according to claim 1, wherein a bottom surface of the SiGe Fin facing the substrate and a bottom surface of the shallow trench isolation region facing the substrate are coplanar; or a bottom surface of the SiGe Fin facing the substrate is higher than a bottom surface of the shallow trench isolation region facing the substrate; or a bottom surface of the SiGe Fin facing the substrate is lower than a bottom surface of the shallow trench isolation region facing the substrate.

4. The semiconductor device according to claim 1, wherein a cross section of a bottom surface of the SiGe Fin facing the substrate is a horizontal plane, an arcuate plane, or a triangular plane.

5. The semiconductor device according to claim 1, wherein a width of the middle Si_{y}Ge_{1-y} layer of the SiGe Fin is 1/5 to 1/2 of a width of the entire SiGe Fin.

6. The semiconductor device according to claim 1, wherein a stress layer is disposed between the shallow trench isolation region and the oxide layer.

7. The semiconductor device according to claim 1, wherein a concentration of Si in the middle Si_{y}Ge_{1-y} layer of the SiGe Fin is 3% to 30% higher than that in the SiₓGe₁₋ₓ or Si_{z}Ge_{1-z} layer on both sides.

8. The semiconductor device according to claim 1, wherein a SiGe layer or a pure Ge layer is disposed between a bottom surface of the SiGe Fin facing the substrate and the substrate, and a content of Ge in the SiGe layer is higher than that in the SiGe Fin.

9. The semiconductor device according to claim 8, wherein a concentration of Ge in the middle Si_{y}Ge_{1-y} layer of the SiGe Fin is 3% to 30% higher than that in the SiₓGe₁₋ₓ or Si_{z}Ge_{1-z} layer on both sides.

10. A method for manufacturing a semiconductor device, comprising:
forming a shallow trench isolation region in a substrate, wherein a portion of the substrate between the shallow trench isolation regions comprises a bulk silicon Fin structure;
selectively removing the bulk silicon Fin structure, recessing the bulk silicon Fin structure to form a trench, and growing a semiconductor material at the trench to form a SiGe Fin, wherein the SiGe Fin is a sandwich-like SiₓGe₁₋ₓ/Si_{y}Ge_{1-y}/Si_{z}Ge_{1-z} structure with different Ge contents in a horizontal direction;
recessing the shallow trench isolation region to cause a top surface of the SiGe Fin facing away from the substrate to protrude from the shallow trench isolation regions on both sides.

11. The method according to claim 10, wherein forming the shallow trench isolation region further comprises:
forming the bulk silicon Fin structure and the trench on the substrate by a sidewall pattern transfer technique or other photolithography techniques;
filling a dielectric material to cover the trench and a top surface of the bulk silicon Fin structure;
performing CMP or etching back the dielectric material to expose the top surface of the bulk silicon Fin structure.

12. The method according to claim 10, wherein an oxide layer is formed on a sidewall and the top surface of the bulk silicon Fin structure.

13. The method according to claim 10, wherein before forming the SiGe Fin, the method further comprises:
mechanically planarizing the semiconductor material to remove the semiconductor material located on the top surface of the shallow trench isolation region.

14. The method according to claim 10, wherein when the bulk silicon Fin structure is selectively removed, the bulk silicon Fin structure is partially or completely removed or even the substrate is recessed, and a cross-section of a surface facing the substrate after removal comprises a horizontal plane, an arcuate plane, or a triangular plane.

15. The method according claim 10, wherein a width of a middle Si_{y}Ge_{1-y} layer of the SiGe Fin with the sandwich-like structure is 1/5 to 1/2 of a width of the SiGe Fin.

16. The method according to claim 10, wherein a stress layer is disposed between the shallow trench isolation region and the oxide layer.

17. The method according to claim 10, wherein a concentration of Si in the middle Si_{y}Ge_{1-y} layer of the semiconductor material of the SiGe Fin with the sandwich-like structure is 3% to 30% higher than that in the SiₓGe₁₋ₓ or Si_{z}Ge_{1-z} layer on both sides.

18. The method according to claim 10, wherein after selectively removing the bulk silicon Fin structure and before growing the semiconductor material, a SiGe layer or a pure Ge layer is selectively formed in the trench by a reduced pressure chemical vapor deposition, and a content of Ge in the SiGe layer or the pure Ge layer is higher than that in the SiGe Fin.

19. The method according to claim 18, wherein a concentration of Ge in the middle SiGe layer of the SiGe Fin with the sandwich-like structure is 3% to 30% higher than that in the SiₓGe₁₋ₓ or Si_{z}Ge_{1-z} layer on both sides.

20. An electronic device comprising an integrated circuit formed of the semiconductor device according to claim 1.
